(19) United States
(12) Patent Application Publication
(10) Pub. No.: US 2013/0001759 A1
(43) Pub. Date: Jan. 3, 2013

(54) SEMICONDUCTOR PACKAGE AND METHOD OF MANUFACTURING THE SEMICONDUCTOR PACKAGE

(75) Inventors: Tae Hyun Kim, Gyunggi-do (KR); Eun Jung Jo, Gyunggi-do (KR); Jae Hyun Lim, Gyunggi-do (KR); Joon Seok Chae, Gyunggi-do (KR); Young Ho Sohn, Gyunggi-do (KR)

(73) Assignee: SAMSUNG ELECTRO-MECHANICS CO., LTD., Gyunggi-do (KR)

(21) Appl. No.: 13/614,555

(22) Filed: Sep. 13, 2012

(30) Foreign Application Priority Data
Jun. 29, 2011 (KR) 10-2012-0070786

(51) Int. Cl. H01L 23/495; H01L 21/58

(52) U.S. Cl. 257/675; 438/122; 257/E23.051; 257/E21.505

(57) ABSTRACT

Disclosed herein is a semiconductor package including: first power device; second power device formed in an upper portion of the first power device; a first lead frame formed in a lower portion of the first power device; a second lead frame formed in the upper portion of the first power device and a lower portion of the second power device; a third lead frame formed in an upper portion of the second power device; a fourth lead frame electrically connected to at least one of the power device and the second power device; and a sealing substance exposing a part of the first through fourth lead frames and sealing the other parts thereof.

### CROSS REFERENCE TO RELATED APPLICATION

This application claims the benefit of Korean Patent Application No. 10-2012-0070786, filed on Jun. 29, 2012, entitled “Semiconductor Package and Method of Manufacturing the Semiconductor Package”, which is hereby incorporated by reference in its entirety into this application.

### BACKGROUND OF THE INVENTION

1. Technical Field

The present invention relates to a semiconductor package and a method of manufacturing the semiconductor package.

2. Description of the Related Art

Generally, a semiconductor package is used by loading one or a plurality of power devices or control devices on a lead frame or a printed circuit board, sealing them using sealing resin, and protecting the inside thereof, and mounting them in a mother board or a system printed circuit board.

However, as high speed, mass storage, and high integration electronic devices have rapidly been developed, power devices applied to cars, industrial devices, and home electronic appliances also face demand for achieving small sized and light weighted power devices at low cost. A single method of solving the above demand is to form a semiconductor package in which a plurality of power devices are loaded. The semiconductor package includes a power device and a control device. In particular, the power device generates a large amount of heat compared to other control devices. Thus, to effectively dissipate the generated heat to the outside is emerging as an important tissue so as to maintain a high reliability for a long period of time. A conventional semiconductor package has a structure in which power devices and control devices are laminated, are connected to lead frames via wire bonding, and are molded by a sealing substance (U.S. Pat. No. 6,087,722).

### SUMMARY OF THE INVENTION

The present invention has been made in an effort to provide a semiconductor package capable of being light, thin, short, and small, and a method of manufacturing the semiconductor package.

Further, the present invention has been made in an effort to provide a semiconductor package having improved performance of heat dissipation, and a method of manufacturing the semiconductor package.

According to a first preferred embodiment of the present invention, there is provided a semiconductor package including: one or more first power device; one or more second power device formed in an upper portion of the one or more first power device; a first lead frame formed in a lower portion of the one or more first power device and electrically connected to the one or more first power device; a second lead frame formed in the upper portion of the one or more first power device and a lower portion of the one or more second power device and electrically connected to the one or more first power device and the one or more second power device; a third lead frame formed in an upper portion of the one or more second power device and electrically connected to the one or more second power device; a fourth lead frame electrically connected to at least one of the one or more first power device and the one or more second power device; and a sealing substance exposing a part of the first through fourth lead frames and sealing the other parts thereof.

The first through third lead frames may be exposed to the outside of the sealing substance on the same line.

The fourth lead frame may be connected to at least one of the one or more first power device and the one or more second power device through wire bonding.

The fourth lead frame may include a 4-1th lead frame electrically connected to the one or more first power device and a 4-2th lead frame electrically connected to the one or more second power device.

The semiconductor package may further include: a control device formed in an upper portion or a lower portion of the fourth lead frame and electrically connected to the fourth lead frame.

The control device may be connected to at least one of the one or more first power device and the one or more second power device through wire bonding.

The semiconductor package may further include: a heat dissipation means formed in at least one of an upper portion and a lower portion of the sealing substance.

The first through fourth lead frames may include: a conductive substrate in which a connection unit directly connected to the one or more first power device or the one or more second power device is formed; and an insulation member formed to surround a region of the conductive substrate other than the connection unit.

According to a second preferred embodiment of the present invention, there is provided a method of manufacturing a semiconductor package, the method including: forming a first lead frame; forming one or more first power device in an upper portion of the first lead frame; forming a second lead frame in an upper portion of the one or more first power device; forming one or more second power device in an upper portion of the second lead frame; forming a third lead frame in an upper portion of the one or more second power device; forming a fourth lead frame; electrically connecting the fourth lead frame to at least one of the one or more first power device and the one or more second power device; and exposing a part of the first through fourth lead frames and sealing the other parts thereof by using a sealing substance.

The first through third lead frames may be exposed to the outside of the sealing substance on the same line.

In the forming of fourth lead frame, the fourth lead frame may include a 4-1th lead frame electrically connected to the one or more first power device and a 4-2th lead frame electrically connected to the one or more second power device.

In the electrically connecting of the fourth lead frame to at least one of the one or more first power device and the one or more second power device, the fourth lead frame may be connected to at least one of the one or more first power device and the one or more second power device through wire bonding.

The method may further include: after the forming of the fourth lead frame, forming a control device in an upper portion or a lower portion of the fourth lead frame, the control device electrically connected to the fourth lead frame.

The method may further include: after the forming of the control device, electrically connecting the control device to at least one of the one or more first power device and the one or more second power device.

In the electrically connecting of the control device to at least one of the one or more first power device and the one or more second power device, the control device may be connected to at least one of the one or more first power device and the one or more second power device through wire bonding.

The first through fourth lead frames may include: a conductive substrate in which a connection unit electrically connected to the one or more first power device or the one or more second power device is formed; and an insulation member formed to surround a region of the conductive substrate other than the connection unit.

The method may further include: after the sealing of the other parts thereof by using the sealing substance, forming a heat dissipation means in at least one of an upper portion and a lower portion of the sealing substance.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplary view of a semiconductor package according to an embodiment of the present invention;

FIG. 2 is an exemplary view of a lead frame according to an embodiment of the present invention;

FIGS. 3 through 8 are exemplary views for describing a laminating method for semiconductor packaging according to an embodiment of the present invention;

FIG. 9 is an exemplary view of a semiconductor package according to another embodiment of the present invention;

FIG. 10 is an exemplary view of a semiconductor package according to another embodiment of the present invention; and

FIGS. 11 and 12 are exemplary views of a semiconductor package mounted in a printed board assembly (PBA).

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

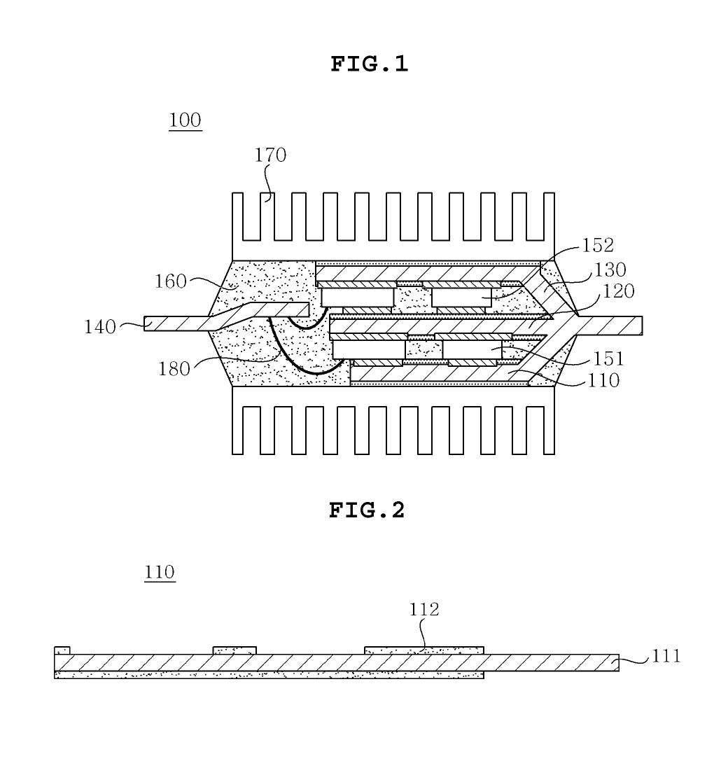

FIG. 1 is an exemplary view of a semiconductor package 100 according to an embodiment of the present invention.

Referring to FIG. 1, the semiconductor package 100 may include a first power device 151, a second power device 152, a first lead frame 110, a second lead frame 120, a third lead frame 130, a fourth lead frame 140, a sealing substance 160, and a heat dissipation means 170.

The first power device 151 and the second power device 152 may include a power MOSFET, a bipolar junction transistor (BJT), an insulated gate bipolar transistor (IGBT), diode, or a combination thereof. Pad portions that are electrically connected to the first lead frame 110 through the fourth lead frame 140 may be formed in upper or lower portions of the first power device 151 and the second power device 152.

The first lead frame 110 may be formed in the lower portion of the first power device 151. The first lead frame 110 may be directly bonded to the pad portion formed in the lower portion of the first power device 151 and may be electrically connected to the pad portion.

The second lead frame 120 may be formed in the upper portion of the first power device 151 and the lower portion of the second power device 152. The second lead frame 120 may be directly bonded to the pad portion formed in the upper portion of the first power device 151 and the pad portion formed in the lower portion of the second power device 152 and may be electrically connected to the pad portions.

The third lead frame 130 may be formed in the upper portion of the second power device 152. The third lead frame 130 may be directly bonded to the pad portion formed in the upper portion of the second power device 152 and may be electrically connected to the pad portion.

According to an embodiment of the present invention, the first lead frame 110 through the third lead frame 130 may be directly bonded to the first power device 151 or the second power device 152 by using conductive materials. For example, the conductive materials may be a solder, a solder paste, silver (Ag) paste, or a combination thereof.

Also, at least one of the first lead frame 110 through the third lead frame 130 may be a power bus line. Also, the first lead frame 110 through the third lead frame 130 may be formed to have a down-set structure so that the first lead frame 110 through the third lead frame 130 may be disposed on the same line outside the semiconductor package 100.

The fourth lead frame 140 may be spaced apart from the first power device 151 and the second power device 152. The fourth lead frame 140 may be electrically connected to the first power device 151 and the second power device 152 via a wire 180. The wire 180 may be formed of a conductive material. For example, the wire 180 may include aluminum (Al), gold (Au), and an alloy of each of these. The fourth lead frame 140 may be a signal line.

According to an embodiment of the present invention, the first lead frame 110 through the third lead frame 130 including the power bus line and the fourth lead frame 140 that is the signal line are formed to be exposed to the outside of the semiconductor package 100 in different directions, thereby easily obtaining insulation distances between insulation leads.

The sealing substance 160 may be formed to entirely cover and seal the first lead frame 110 through the fourth lead frame 140 excluding a part of the first lead frame 110 through the fourth lead frame 140. Also, the sealing substance 160 may be formed to allow the lower portion of the first lead frame 110 and the upper portion of the third lead frame 130 to be exposed. In this regard, the sealing substance 160 may cover and seal a part of the down-set structure of the first lead frame 110 and the third lead frame 130. Thus, the first lead frame 110 through the fourth lead frame 140 that are exposed to the outside of the sealing substance 160 may be disposed on the same horizontal line. In this regard, the first lead frame 110 through the fourth lead frame 140 exposed to the outside of the sealing substance 160 may be electrically connected to the outside of the semiconductor package 100. The sealing substance 160 may be formed of insulation resin. For example, the sealing substance 160 may include an epoxy molding compound (EMC), polyimide, silicon, silicon rubber or a combination thereof.

The heat dissipation means 170 may be formed to dissipate heat of the semiconductor package 100. The heat dissipation means 170 may be formed in at least one of an upper portion and a lower portion of the sealing substance 160. According to an embodiment of the present invention, the heat dissipation means 170 may be formed in each of the upper and lower portions of the sealing substance 160 to improve heat dissipation performance. In this regard, the heat dissipation means 170 may be formed to be directly bonded to the lower portion of the first lead frame 110 and the upper portion of the third lead frame 130 that are exposed to the outside by the sealing substance 160. As such, the heat dissipation means 170 is directly bonded to the first lead frame 110 and the third lead frame 130, thereby effectively heating heat generated by the first power device 151 and the second power device 152. The heat dissipation means 170 may include a heat sink. The heat sink may include metal, a metal nitride, ceramic, resin, or a combination thereof. For example, the heat sink may include aluminum, an aluminum alloy, copper, a copper alloy, Al2O3, BeO, AlN, SiN, epoxy based resin, or a combination thereof. The heat dissipation means 170 may have various sizes and shapes so as to more effectively dissipate the heat.

Although the first lead frame 110 through the third lead frame 130 are formed in the same direction, and the fourth lead frame 140 is formed in a different direction according to an embodiment of the present invention, a structure of the semiconductor package 100 is not limited thereto. That is, if the semiconductor package 100 according to an embodiment of the present invention may include the first lead frame 110 through the third lead frame 130 of a 3-step structure, the fourth lead frame 140 is formed in any different directions.

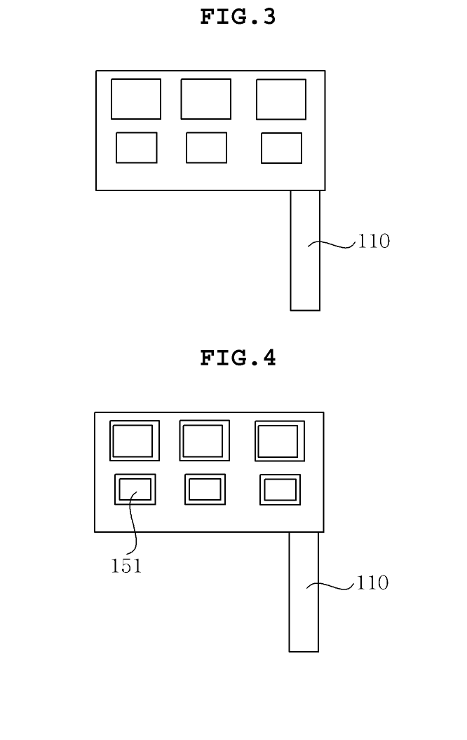

FIG. 2 is an exemplary view of the first lead frame 110 according to an embodiment of the present invention.

Referring to FIG. 2, the first lead frame 110 may include a conductive substrate 111 and an insulation member 112. The conductive substrate 111 may be directly connected to a power device and may be electrically connected thereto. The conductive substrate 111 may be formed of a conductive material. For example, the conductive substrate 111 may be formed of a conductive metal such as copper (Cu), nickel (Ni), gold (Au), etc. The insulation member 112 may be formed to surround a region of the conductive substrate 111 in addition to a connection unit directly connected to the power device. The insulation member 112 may be formed of an insulation material. For example, the insulation member 112 may be formed of ceramic or epoxy and thus bonding to the sealing substance 160 as well as insulation may be improved.

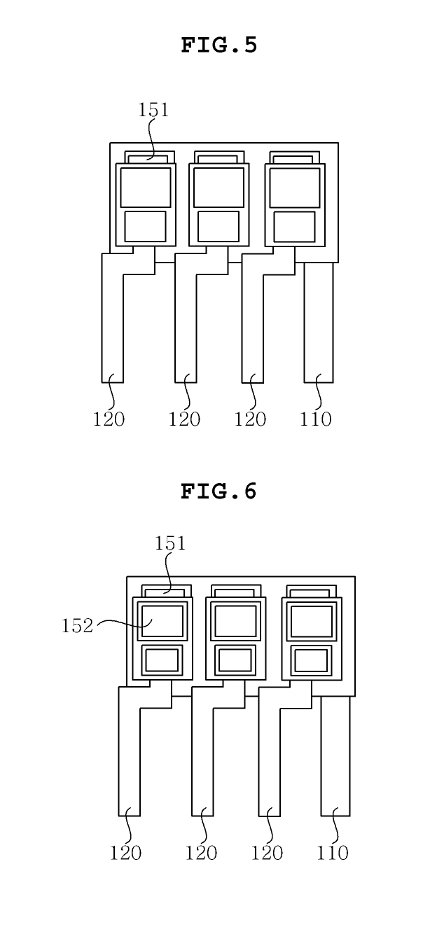

FIGS. 3 through 8 are exemplary views for describing a laminating method for semiconductor packaging according to an embodiment of the present invention.

Referring to FIG. 3, the first lead frame 110 may be formed. The first lead frame 110 may include the conductive substrate 111 and the insulation member 112. The insulation member 112 may be formed in the first lead frame 110 to allow the first power device 151 or the conductive substrate 111 of a part contacting the outside to be exposed. Although not shown in FIG. 3, the first lead frame 110 may include an upward down-set structure.

Referring to FIG. 4, the first power device 151 may be formed in an upper portion of the first lead frame 110. That is, the upper portion of the first lead frame 110 and a lower portion of the first power device 151 may be electrically connected to each other. One or more first power devices 151 may be mounted in the first lead frame 110. The first power device 151 may include a power MOSFET, a BJT, an IGBT, diode, or a combination thereof. The first power device 151 may be bonded to the first lead frame 110 by using a conductive material. For example, the conductive material may be a solder, a solder paste, silver (Ag) paste, or a combination thereof.

Referring to FIG. 5, the second lead frame 120 may be formed in the upper portion of the first power device 151. That is, a lower portion of the second lead frame 120 and the upper portion of the first power device 151 may be electrically connected to each other. The second lead frame 120 may include the conductive substrate 111 and the insulation member 112, like the first lead frame 110. The insulation member 112 may be formed in the second lead frame 120 to allow the first power device 151, the second power device 152, or the conductive substrate 111 of a part contacting the outside to be exposed. The second lead frame 120 may be bonded to the first power device 151 by using a conductive material such as a solder, a solder paste, silver (Ag) paste, or a combination thereof.

Referring to FIG. 6, the second power device 152 may be formed in an upper portion of the second lead frame 120. That is, the upper portion of the second lead frame 120 and a lower portion of the second power device 152 may be electrically connected to each other. One or more second power devices 152 may be mounted in the second lead frame 120. The second power device 152 may include a power MOSFET, a BJT, an IGBT, diode, or a combination thereof. The second power device 152 may be bonded to the second lead frame 120 by using a conductive material. For example, the conductive material may be a solder, a solder paste, silver (Ag) paste, or a combination thereof.

Referring to FIG. 7, the third lead frame 130 may be formed in the upper portion of the second power device 152. That is, a lower portion of the third lead frame 130 and the upper portion of the second power device 152 may be electrically connected to each other. The third lead frame 130 may include the conductive substrate 111 and the insulation member 112, like the first lead frame 110. The insulation member 112 may be formed in the third lead frame 130 to allow the second power device 152 or the conductive substrate 111 of a part contacting the outside to be exposed. The third lead frame 130 may be bonded to the second power device 152 by using a conductive material such as a solder, a solder paste, silver (Ag) paste, or a combination thereof.

Referring to FIG. 8, the fourth lead frame 140 may be formed. One or more fourth lead frames 140 may be formed. According to an embodiment of the present invention, in a case where the first power device 151 and the second power device 152 are plural, the fourth lead frame 140 may also be plural. The plurality of fourth lead frames 140 may be electrically connected to each of the first power devices 151 and the second power devices 152. The connection between the fourth lead frames 140 and the first power devices 151 and the second power devices 152 may be made via wire bonding as shown in FIG. 8. However, the connection between the fourth lead frames 140 and the first power devices 151 and the second power devices 152 is not limited to the wire bonding. That is, the fourth lead frames 140 may be directly bonded to the first power devices 151 and the second power devices 152.

In FIG. 8, the fourth lead frames 140 are formed in opposite directions to the first lead frame 110 through the third lead frame 130. However, the locations of the fourth lead frames 140 are not limited thereto and may be easily modified by one of ordinary skill in the art.

In an embodiment of the present invention, the connection between the fourth lead frames 140 and the first power devices 151 and the second power devices 152 is described. However, in a case where control devices (not shown) are formed in the fourth lead frames 140, the first power devices 151 and the second power devices 152 may be connected to the control devices (not shown).

After the first lead frame 110 through the fourth lead frame 140, the first power device 151, and the second power device 152 are laminated according to the above-described sequence, a sequence may follow a known process. That is, after a laminating process, the first lead frame 110 through the fourth lead frame 140, the first power device 151, and the second power device 152 are sealed by using a sealing substance 160, and a process of forming a heat dissipation means may be performed according to an already known technology.

Although the fourth lead frame 140 is formed after the first lead frame 110 through the third lead frame 130 are formed in an embodiment of the present invention, a sequence for forming the fourth lead frame 140 is not limited thereto. That is, a process of laminating the fourth lead frame 140 may be performed at any sequences.

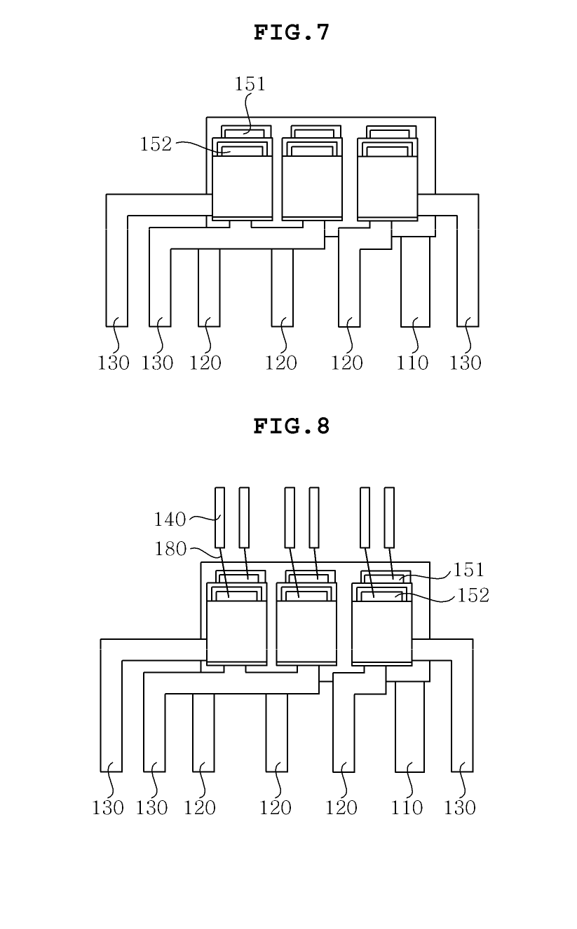

FIG. 9 is an exemplary view of the semiconductor package 100 according to another embodiment of the present invention.

Referring to FIG. 9, the semiconductor package 100 may include the first power device 151, the second power device 152, the first lead frame 110, the second lead frame 120, the third lead frame 130, the fourth lead frame 140, the sealing substance 160, and the heat dissipation means 170.

The first power device 151 and the second power device 152 may include a power MOSFET, a BJT, an IGBT, diode, or a combination thereof.

The first lead frame 110 may be formed in the lower portion of the first power device 151. The first lead frame 110 may be directly bonded to a pad portion formed in a lower portion of the first power device 151 and may be electrically connected to the pad portion.

The second lead frame 120 may be formed in the upper portion of the first power device 151 and the lower portion of the second power device 152. The second lead frame 120 may be directly bonded to a pad portion formed in an upper portion of the first power device 151 and a pad portion formed in a lower portion of the second power device 152 and may be electrically connected to the pad portions.

The third lead frame 130 may be formed in an upper portion of the second power device 152. The third lead frame 130 may be directly bonded to a pad portion formed in the upper portion of the second power device 152 and may be electrically connected to the pad portion.

According to an embodiment of the present invention, the first lead frame 110 through the third lead frame 130 may be directly bonded to the first power device 151 or the second power device 152 by using conductive materials. For example, the conductive materials may be a solder, a solder paste, silver (Ag) paste, or a combination thereof.

Also, at least one of the first lead frame 110 through the third lead frame 130 may be a power bus line. Also, the first lead frame 110 through the third lead frame 130 may be formed to have a down-set structure so that the first lead frame 110 through the third lead frame 130 may be disposed on the same line outside the semiconductor package 100.

The fourth lead frame 140 may be spaced apart from the first power device 151 and the second power device 152. The fourth lead frame 140 may include a 4-1th lead frame 141 and a 4-2th lead frame 142. The 4-1th lead frame 141 may be directly bonded to the first power device 151. The 4-2th lead frame 142 may be directly bonded to the second power device 152. The 4-1th lead frame 141 and the 4-2th lead frame 142 may be formed to have the down-set structure. Thus, the 4-1th lead frame 141 and the 4-2th lead frame 142 projecting to the outside of the sealing substance 160 may be disposed on the same horizontal line. The above-formed fourth lead frame 140 may be a signal line.

According to an embodiment of the present invention, the first lead frame 110 through the third lead frame 130 including the power bus line and the fourth lead frame 140 that is the signal line are formed to be exposed to the outside of the semiconductor package 100 in different directions, thereby easily obtaining insulation distances between insulation leads.

The sealing substance 160 may be formed to entirely cover and seal the first lead frame 110 through the fourth lead frame 140 excluding a part of the first lead frame 110 through the fourth lead frame 140. Also, the sealing substance 160 may be formed to allow the lower portion of the first lead frame 110 and the upper portion of the third lead frame 130 to be exposed. In this regard, the sealing substance 160 may cover and seal a part of the down-set structure of the first lead frame 110 and the third lead frame 130. Thus, the first lead frame 110 through the fourth lead frame 140 that are exposed to the outside of the sealing substance 160 may be disposed on the same horizontal line. In this regard, the first lead frame 110 through the fourth lead frame 140 exposed to the outside of the sealing substance 160 may be electrically connected to the outside of the semiconductor package 100. The sealing substance 160 may be formed of insulation resin. For example, the sealing substance 160 may include an EMC, polyimide, silicon, silicon rubber or a combination thereof.

The heat dissipation means 170 may be formed to dissipate heat of the semiconductor package 100. The heat dissipation means 170 may be formed in at least one of an upper portion and a lower portion of the sealing substance 160. According to an embodiment of the present invention, the heat dissipation means 170 may be formed in each of the upper and lower portions of the sealing substance 160 to improve heat dissipation performance. In this regard, the heat dissipation means 170 may be formed to be directly bonded to the lower portion of the first lead frame 110 and the upper portion of the third lead frame 130 that are exposed to the outside by the sealing substance 160. As such, the heat dissipation means 170 is directly bonded to the first lead frame 110 and the third lead frame 130, thereby effectively heating heat generated by the first power device 151 and the second power device 152. The heat dissipation means 170 may include a heat sink. The heat sink may include metal, a metal nitride, ceramic, resin, or a combination thereof. For example, the heat sink may include aluminum, an aluminum alloy, copper, a copper alloy, Al2O3, BeO, AlN, SiN, epoxy based resin, or a combination thereof. The heat dissipation means 170 may have various sizes and shapes to more effectively dissipate the heat.

Although the first lead frame 110 through the third lead frame 130 are formed in the same direction and the fourth lead frame 140 is formed in a different direction according to an embodiment of the present invention, a structure of the semiconductor package 100 is not limited thereto. That is, if the semiconductor package 100 according to an embodiment of the present invention may include the first lead frame 110 through the third lead frame 130 of a 3-step structure, the fourth lead frame 140 is formed in any different directions.

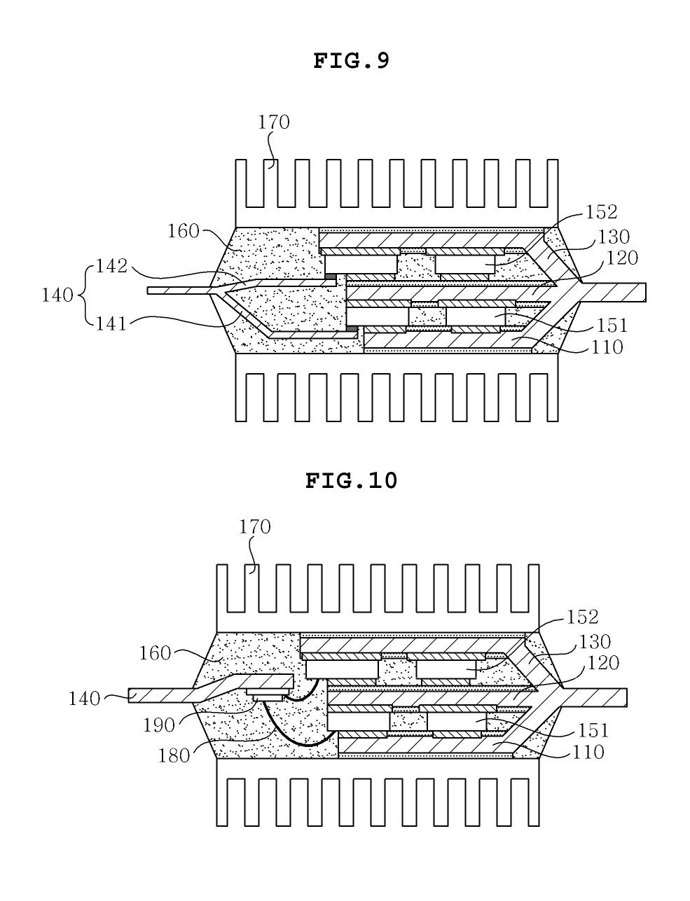

FIG. 10 is an exemplary view of a semiconductor package 100 according to another embodiment of the present invention.

Referring to FIG. 10, the semiconductor package 100 may include the first power device 151, the second power device 152, the first lead frame 110, the second lead frame 120, the third lead frame 130, the fourth lead frame 140, the sealing substance 160, the heat dissipation means 170, and a control device 190.

The first power device 151 and the second power device 152 may include a power MOSFET, a BJT, an IGBT, diode, or a combination thereof. Pad portions that are electrically connected to the first lead frame 110 through the fourth lead frame 140 may be formed in upper or lower portions of the first power device 151 and the second power device 152.

The first lead frame 110 may be formed in the lower portion of the first power device 151. The first lead frame 110 may be directly bonded to a pad portion formed in a lower portion of the first power device 151 and may be electrically connected to the pad portion.

The second lead frame 120 may be formed in the upper portion of the first power device 151 and the lower portion of the second power device 152. The second lead frame 120 may be directly bonded to a pad portion formed in an upper portion of the first power device 151 and a pad portion formed in a lower portion of the second power device 152 and may be electrically connected to the pad portions.

The third lead frame 130 may be formed in an upper portion of the second power device 152. The third lead frame 130 may be directly bonded to a pad portion formed in the upper portion of the second power device 152 and may be electrically connected to the pad portion.

According to an embodiment of the present invention, the first lead frame 110 through the third lead frame 130 may be directly bonded to the first power device 151 or the second power device 152 by using conductive materials. For example, the conductive materials may be a solder, a solder paste, silver (Ag) paste, or a combination thereof.

Also, at least one of the first lead frame 110 through the third lead frame 130 may be a power bus line. Also, the first lead frame 110 through the third lead frame 130 may be formed to have a down-set structure so that the first lead frame 110 through the third lead frame 130 may be disposed on the same line outside the semiconductor package 100.

The fourth lead frame 140 may be spaced apart from the first power device 151 and the second power device 152. The control device 190 may be formed in an upper portion of the fourth lead frame 140. The fourth lead frame 140 in which the control device 190 is mounted may be a signal line.

The control device 190 may be electrically connected to the fourth lead frame 140. The semiconductor package 100 may include a plurality of control devices 190. The plurality of control devices 190 may be formed in a laminated structure. Each of the plurality of control devices 190 may be electrically connected to the first power device 151 and the second power device 152. In this regard, the control devices 190 may be connected to the first power device 151 and the second power device 152 via the wire 180. The wire 180 may be formed of a conductive material. For example, the wire 180 may include aluminum (Al), gold (Au), and an alloy of each of these.

According to an embodiment of the present invention, the first lead frame 110 through the third lead frame 130 including the power bus line and the fourth lead frame 140 that is the signal line are formed to be exposed to the outside of the semiconductor package 100 in different directions, thereby easily obtaining insulation distances between insulation leads.

The sealing substance 160 may be formed to entirely cover and seal the first lead frame 110 through the fourth lead frame 140 excluding a part of the first lead frame 110 through the fourth lead frame 140. Also, the sealing substance 160 may be formed to allow the lower portion of the first lead frame 110 and the upper portion of the third lead frame 130 to be exposed. In this regard, the sealing substance 160 may cover and seal a part of the down-set structure of the first lead frame 110 and the third lead frame 130. Thus, the first lead frame 110 through the fourth lead frame 140 that are exposed to the outside of the sealing substance 160 may be disposed on the same horizontal line. In this regard, the first lead frame 110 through the fourth lead frame 140 exposed to the outside of the sealing substance 160 may be electrically connected to the outside of the semiconductor package 100. The sealing substance 160 may be formed of insulation resin. For example, the sealing substance 160 may include an EMC, polyimide, silicon, silicon rubber or a combination thereof.

The heat dissipation means 170 may be formed to dissipate heat of the semiconductor package 100. The heat dissipation means 170 may be formed in at least one of an upper portion and a lower portion of the sealing substance 160. According to an embodiment of the present invention, the heat dissipation means 170 may be formed in each of the upper and lower portions of the sealing substance 160 to improve heat dissipation performance. In this regard, the heat dissipation means 170 may be formed to be directly bonded to the lower portion of the first lead frame 110 and the upper portion of the third lead frame 130 that are exposed to the outside by the sealing substance 160. As such, the heat dissipation means 170 is directly bonded to the first lead frame 110 and the third lead frame 130, thereby effectively heating heat generated by the first power device 151 and the second power device 152. The heat dissipation means 170 may include a heat sink. The heat sink may include metal, a metal nitride, ceramic, resin, or a combination thereof. For example, the heat sink may include aluminum, an aluminum alloy, copper, a copper alloy, Al2O3, BeO, AlN, SiN, epoxy based resin, or a combination thereof. The heat dissipation means 170 may have various sizes and shapes to more effectively dissipate the heat.

Although the first lead frame 110 through the third lead frame 130 are formed in the same direction and the fourth lead frame 140 is formed in a different direction according to an embodiment of the present invention, a structure of the semiconductor package 100 is not limited thereto. That is, if the semiconductor package 100 according to an embodiment of the present invention may include the first lead frame 110 through the third lead frame 130 of a 3-step structure, the fourth lead frame 140 is formed in any different directions.

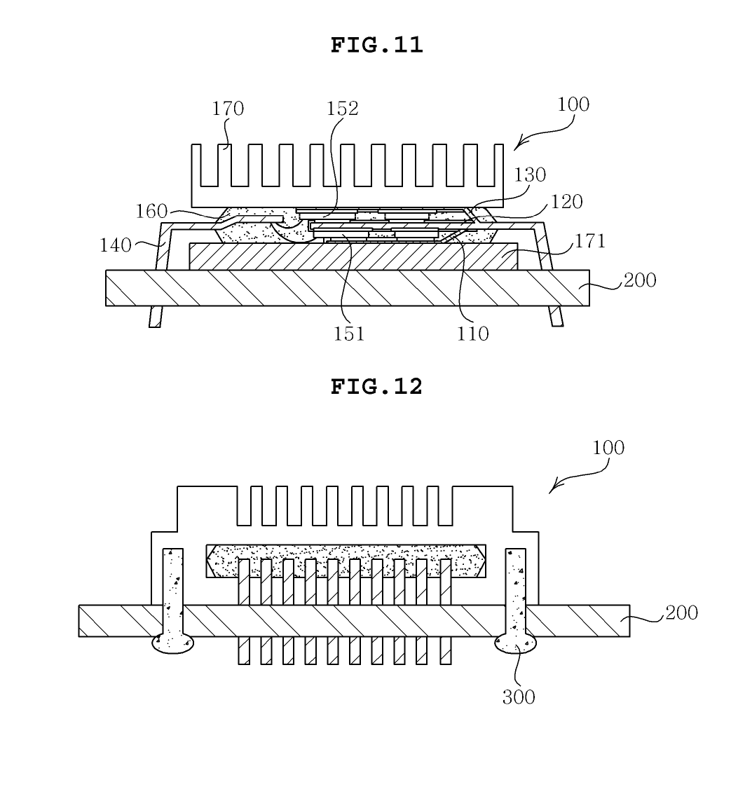

FIGS. 11 and 12 are exemplary views of a semiconductor package mounted in a printed board assembly (PBA) 200.

Referring to FIG. 11, a cross-section of the semiconductor package 100 mounted in an upper portion of the PBA 200 may be acknowledged.

Also, referring to FIG. 12, a side surface of the semiconductor package 100 mounted in the upper portion of the PBA 200 may be acknowledged.

The semiconductor package 100 may be formed in a structure in which the first lead frame 110 through the third lead frame 130, the first power device 151, and the second power device 152 are laminated. Also, the semiconductor package 100 may include the fourth lead frame 140 electrically connected to the first power device 151 and the second power device 152. The semiconductor package 100 may include the sealing substance 160 formed to wholly seal the first lead frame 110 through the fourth lead frame 140 excluding parts connected to the outside. In an embodiment of the present invention, the first lead frame 110 through the third lead frame 130 and the fourth lead frame 140 may protrude in directions opposite to each other. The semiconductor package 100 may include the heat dissipation means 170 and a heat dissipation means 171 in upper and lower portions of the sealing substance 160, respectively. In this regard, to enable the semiconductor package 100 to be easily mounted in the PBA 200, a shape of the heat dissipation means 171 formed in the lower portion of the sealing substance 160 may change.

The first lead frame 110 through the fourth lead frame 140 exposed to the outside of the semiconductor package 100 may be inserted and fixed in the PBA 200.

As such, after the semiconductor package 100 is mounted in the PBA 200, the semiconductor package 100 and the PBA 200 may be engaged with each other via a screw 300 to be fixed to each other as shown in FIG. 12.

In a semiconductor package and a method of manufacturing the semiconductor package according to an embodiment of the present invention, a structure in which power devices are laminated makes it possible to achieve a light, thin, short, and small semiconductor package. Also, in a semiconductor package and a method of manufacturing the semiconductor package according to an embodiment of the present invention, lead frames for electrically connecting power devices to the outside have a down-set structure, and thus all lead frames may be formed to be disposed on the same line. Also, in a semiconductor package and a method of manufacturing the semiconductor package according to an embodiment of the present invention, lead frames for power bus lines and signal lines are formed in different directions, thereby sufficiently obtaining insulation distances between insulation leads. Also, in a semiconductor package and a method of manufacturing the semiconductor package according to an embodiment of the present invention, heat dissipation means are formed in both sides, thereby improving heat dissipation performance.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor package comprising:
one or more first power device;
one or more second power device formed in an upper portion of the one or more first power device;
a first lead frame formed in a lower portion of the one or more first power device and electrically connected to the one or more first power device;
a second lead frame formed in the upper portion of the one or more first power device and a lower portion of the one or more second power device and electrically connected to the one or more first power device and the one or more second power device;
a third lead frame formed in an upper portion of the one or more second power device and electrically connected to the one or more second power device;
a fourth lead frame electrically connected to at least one of the one or more first power device and the one or more second power device; and
a sealing substance exposing a part of the first through fourth lead frames and sealing the other parts thereof.

2. The semiconductor package as set forth in claim 1, wherein the first through third lead frames are exposed to the outside of the sealing substance on the same line.

3. The semiconductor package as set forth in claim 1, wherein the fourth lead frame is connected to at least one of the one or more first power device and the one or more second power device through wire bonding.

4. The semiconductor package as set forth in claim 1, wherein the fourth lead frame includes a 4-1th lead frame electrically connected to the one or more first power device and a 4-2th lead frame electrically connected to the one or more second power device.

5. The semiconductor package as set forth in claim 1, further comprising: a control device formed in an upper portion or a lower portion of the fourth lead frame and electrically connected to the fourth lead frame.

6. The semiconductor package as set forth in claim 5, wherein the control device is connected to at least one of the one or more first power device and the one or more second power device through wire bonding.

7. The semiconductor package as set forth in claim 1, further comprising: a heat dissipation means formed in at least one of an upper portion and a lower portion of the sealing substance.

8. The semiconductor package as set forth in claim 1, wherein the first through fourth lead frames include:
a conductive substrate in which a connection unit directly connected to the one or more first power device or the one or more second power device is formed; and
an insulation member formed to surround a region of the conductive substrate other than the connection unit.

9. A method of manufacturing a semiconductor package, the method comprising:
forming a first lead frame;
forming one or more first power device in an upper portion of the first lead frame;
forming a second lead frame in an upper portion of the one or more first power device;
forming one or more second power device in an upper portion of the second lead frame;
forming a third lead frame in an upper portion of the one or more second power device;
forming a fourth lead frame;
electrically connecting the fourth lead frame to at least one of the one or more first power device and the one or more second power device; and
exposing a part of the first through fourth lead frames and sealing the other parts thereof by using a sealing substance.

10. The method as set forth in claim 9, wherein the first through third lead frames are exposed to the outside of the sealing substance on the same line.

11. The method as set forth in claim 9, wherein, in the forming of fourth lead frame, the fourth lead frame includes a 4-1th lead frame electrically connected to the one or more first power device and a 4-2th lead frame electrically connected to the one or more second power device.

12. The method as set forth in claim 9, wherein, in the electrically connecting of the fourth lead frame to at least one of the one or more first power device and the one or more second power device, the fourth lead frame is connected to at least one of the one or more first power device and the one or more second power device through wire bonding.

13. The method as set forth in claim 9, further comprising, after the forming of the fourth lead frame, forming a control device in an upper portion or a lower portion of the fourth lead frame, the control device electrically connected to the fourth lead frame.

14. The method as set forth in claim 13, further comprising, after the forming of the control device, electrically connecting the control device to at least one of the one or more first power device and the one or more second power device.

15. The method as set forth in claim 14, wherein, in the electrically connecting of the control device to at least one of the one or more first power device and the one or more second power device, the control device is connected to at least one of the one or more first power device and the one or more second power device through wire bonding.

16. The method as set forth in claim 9, wherein the first through fourth lead frames include:
a conductive substrate in which a connection unit electrically connected to the one or more first power device or the one or more second power device is formed; and
an insulation member formed to surround a region of the conductive substrate other than the connection unit.

17. The method as set forth in claim 9, further comprising, after the sealing of the other parts thereof by using the sealing substance, forming a heat dissipation means in at least one of an upper portion and a lower portion of the sealing substance.
